(19) United States
(12) Patent Application Publication
(10) Pub. No.: US 2026/0262543 A1
(43) Pub. Date: Sep. 3, 2026

(54) SEMICONDUCTOR DEVICE AND METHOD OF MANUFACTURING SEMICONDUCTOR DEVICE

(71) Applicant: Kioxia Corporation, Tokyo (JP)

(72) Inventor: Kiyohito NISHIHARA, Hiratsuka (JP)

(73) Assignee: Kioxia Corporation, Tokyo (JP)

(21) Appl. No.: 19/325,533

(22) Filed: Sep. 11, 2025

(30) Foreign Application Priority Data
Mar. 3, 2025 (JP) 2025-032749

(51) Int. Cl. H01L 25/04; H01L 25/00

(52) U.S. Cl. CPC H10W 90/00; H10W 90/24; H10W 90/752; H10W 90/754

(57) ABSTRACT

A semiconductor device and a method of manufacturing a semiconductor device with which deformation of a chip stacked body stacked on a substrate can be reduced. The semiconductor device includes: a substrate; a first stacked body on the substrate, the first stacked body including a plurality of first semiconductor chips that are stacked while being shifted in a direction perpendicular to a stacking direction; and a second stacked body on the substrate, the second stacked body including a plurality of second semiconductor chips that are stacked in the stacking direction, wherein an upper surface of at least one of the plurality of second semiconductor chips and a lower surface of at least one of the plurality of first semiconductor chips are in contact.

### CROSS-REFERENCE TO RELATED APPLICATION

This application is based upon and claims the benefit of priority from Japanese Patent Application No. 2025-032749, filed Mar. 3, 2025, the entire contents of which are incorporated herein by reference.

### FIELD

Embodiments described herein relate generally to a semiconductor device and a method of manufacturing a semiconductor device.

### BACKGROUND

In a semiconductor device having a plurality of semiconductor chips mounted thereon, the plurality of semiconductor chips are sometimes stacked while being shifted in a direction perpendicular to a stacking direction. When a load is applied to a region not in contact with a lower-stage semiconductor chip in the plurality of stacked semiconductor chips, the semiconductor chip may be deformed to cause reduction in yield and reduction in reliability.

### BRIEF DESCRIPTION OF THE DRAWINGS

FIG. 1A is a plan view of a semiconductor device according to a first embodiment.

FIG. 1B is a sectional view of the semiconductor device according to the first embodiment.

FIG. 2A illustrates a stage in a method of manufacturing a semiconductor device according to the first embodiment.

FIG. 2B illustrates a stage in the method of manufacturing the semiconductor device according to the first embodiment.

FIG. 2C illustrates a stage in the method of manufacturing the semiconductor device according to the first embodiment.

FIG. 2D illustrates a stage in the method of manufacturing the semiconductor device according to the first embodiment.

FIG. 3 illustrates a stage in the method of manufacturing the semiconductor device according to the first embodiment.

FIG. 4A is a plan view of a semiconductor device according to a comparative example.

FIG. 4B is a sectional view of the semiconductor device according to the comparative example.

FIG. 5A is a plan view of a semiconductor device according to a modified example of the first embodiment.

FIG. 5B is a sectional view of the semiconductor device according to the modified example of the first embodiment.

FIG. 6A is a plan view of a configuration of a semiconductor device according to a second embodiment.

FIG. 6B is a sectional view of the configuration of the semiconductor device according to the second embodiment.

FIG. 6C is a sectional view of the configuration of the semiconductor device according to the second embodiment.

FIG. 6D is a sectional view of the configuration of the semiconductor device according to the second embodiment.

FIG. 7A is a plan view of a semiconductor device according to a first modified example of the second embodiment.

FIG. 7B is a sectional view of the semiconductor device according to the first modified example of the second embodiment.

FIG. 7C is a sectional view of the semiconductor device according to the first modified example of the second embodiment.

FIG. 8A is a plan view of a semiconductor device according to a second modified example of the second embodiment.

FIG. 8B is a sectional view of the semiconductor device according to the second modified example of the second embodiment.

FIG. 8C is a sectional view of the semiconductor device according to the second modified example of the second embodiment.

FIG. 8D is a sectional view of the semiconductor device according to the second modified example of the second embodiment.

FIG. 9A is a plan view of a configuration of a semiconductor device according to a third embodiment.

FIG. 9B is a sectional view of the configuration of the semiconductor device according to the third embodiment.

### DETAILED DESCRIPTION

One embodiment described herein generally provides a semiconductor device and a method of manufacturing a semiconductor device with which deformation of a chip stacked body stacked on a substrate can be reduced.

In general, according to one embodiment, a semiconductor device includes: a first stacked body provided on a substrate, the first stacked body including a plurality of first semiconductor chips that are stacked while being shifted in a direction perpendicular to a stacking direction; and a second stacked body provided on the substrate, the second stacked body including a plurality of second semiconductor chips that are stacked in the stacking direction. An upper surface of any one of the plurality of second semiconductor chips and a lower surface of any one of the plurality of first semiconductor chips are in contact.

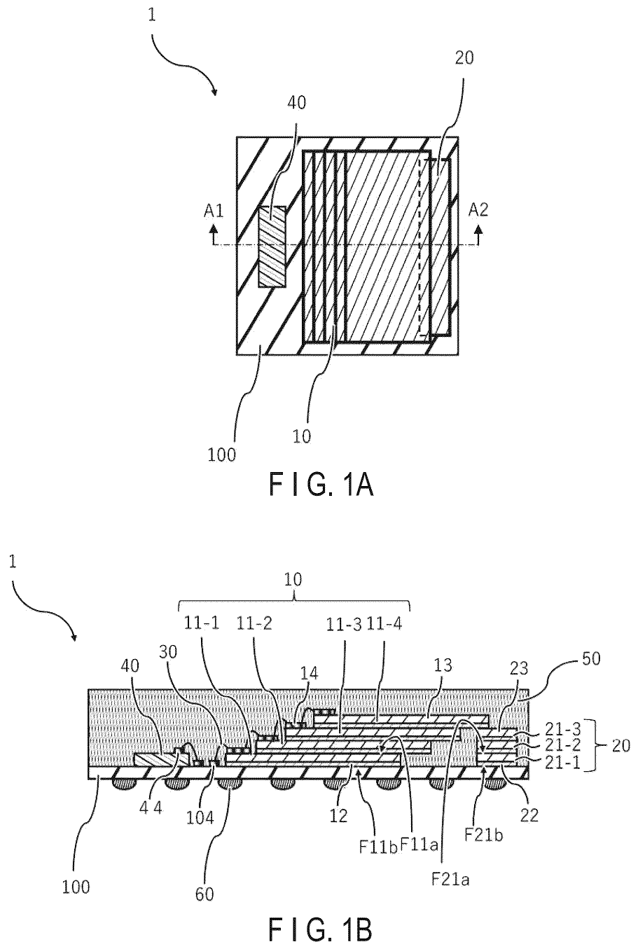

Hereinafter, embodiments are described with reference to the drawings. In FIG. 1A to FIG. 9B, the same or similar configurations are denoted by the same reference symbols, and redundant description is omitted. It is to be noted that the embodiments do not limit the present application.

### (First Embodiment)

FIG. 1A is a plan view of a semiconductor device 1 according to a first embodiment. FIG. 1B is a sectional view obtained by taking the semiconductor device 1 of FIG. 1A along an A1-A2 cross section. In FIG. 1A, a bonding wire 30 and a resin layer 50 are omitted.

As illustrated in FIG. 1B, the semiconductor device 1 includes a substrate 100, a stacked body 10, a stacked body 20, the bonding wire 30, a controller chip 40, the resin layer 50, and a metal terminal 60. The semiconductor device 1 is, for example, a semiconductor package product, and is a NAND flash memory package, a DRAM package, an SSD, an SD card, an eMMC, an UFS, or the like.

The substrate 100 is, for example, a multilayer circuit substrate. The substrate 100 includes a bonding pad 104. The substrate 100 may include a capacitor or a resistor that is not shown.

The stacked body 10 includes a semiconductor chip 11-1, a semiconductor chip 11-2, a semiconductor chip 11-3, and a semiconductor chip 11-4. In the following description, the semiconductor chips 11-1 to 11-4 are each sometimes referred to as “semiconductor chip 11”.

The semiconductor chip 11 includes a chip 13 and an adhesive layer 12. The chip 13 is, for example, a memory chip such as a NAND flash memory or a DRAM, and includes a memory cell array or a CMOS circuit. The adhesive layer 12 is, for example, a DAF (Die Attach Film), and is provided on the lower side in the semiconductor chip 11 and on a lower surface of the chip 13. The stacked body 10 is a stacked body in which the plurality of semiconductor chips 11 are stacked while being shifted (e.g., offset or misaligned) in a direction perpendicular to a stacking direction.

The semiconductor chip 11-1, the semiconductor chip 11-2, the semiconductor chip 11-3, and the semiconductor chip 11-4 each have a first surface F11a and a second surface F11b on a side opposite to the first surface. The first surface F11a of each of the semiconductor chips 11 includes a bonding pad 14.

The stacked body 20 includes a semiconductor chip 21-1, a semiconductor chip 21-2, and a semiconductor chip 21-3. In the following description, the semiconductor chips 21-1 to 21-3 are each sometimes referred to as “semiconductor chip 21.”

The semiconductor chip 21 includes a chip 23 and an adhesive layer 22. The chip 23 is, for example, a memory chip such as a NAND flash memory, and includes a memory cell array or a CMOS circuit. The adhesive layer 22 is, for example, a DAF, and is provided on the lower side in the semiconductor chip 21 and on a lower surface of the chip 23. The stacked body 20 is a stacked body in which the plurality of semiconductor chips 21 are stacked, e.g., vertically aligned. The stacked body 20 has a function of, for example, a spacer that supports the stacked body 10.

The semiconductor chip 21-1, the semiconductor chip 21-2, and the semiconductor chip 21-3 each have a first surface F21a and a second surface F21b on a side opposite to the first surface.

Examples of a material used for the bonding wire 30 include simple materials such as Cu, Ni, W, Au, Ag, Pd, Sn, Bi, Zn, Cr, Al, Ti, Ta, TiN, TaN, and CrN, a composite material of two kinds or more of those materials, and an alloy of two kinds or more of those materials.

The bonding wire 30 electrically connects each of the plurality of semiconductor chips 11 and the bonding pad 104 mounted on the substrate 100. Further, the bonding wire 30 electrically connects a bonding pad 44 mounted on the controller chip 40 and the bonding pad 104 mounted on the substrate 100.

It is to be noted that the first surface F21a of each of the semiconductor chips 21 includes no bonding pad, and the semiconductor chips 21 are not electrically connected to each other. That is, the semiconductor chips 21 are electrically isolated from each other.

The resin layer 50 is formed of, for example, a synthetic resin containing an epoxy resin mixed with an inorganic matter such as silicon dioxide. It is to be noted that the resin layer 50 may be formed of materials containing other synthetic resins. The resin layer 50 seals the stacked body 10, the stacked body 20, the bonding wire 30, and the controller chip 40. The resin layer 50 may seal the capacitor or the resistor that is not shown.

Examples of a material used for the metal terminal 60 include simple materials such as Cu, Ni, W, Au, Ag, Pd, Sn, Bi, Zn, Cr, Al, Ti, Ta, TiN, TaN, and CrN, a composite material of two kinds or more of those materials, and an alloy of two kinds or more of those materials.

A plurality of metal terminals 60 are electrically connected to a plurality of bonding pads 104. Each of the plurality of bonding pads 104 is electrically connected to the bonding pad 14 of the semiconductor chip 11 and the bonding pad 44 of the controller chip 40. The metal terminal 60 is used for, for example, connection to an external device that is not shown.

Hereinafter, a method of manufacturing the semiconductor device 1 according to the first embodiment is described.

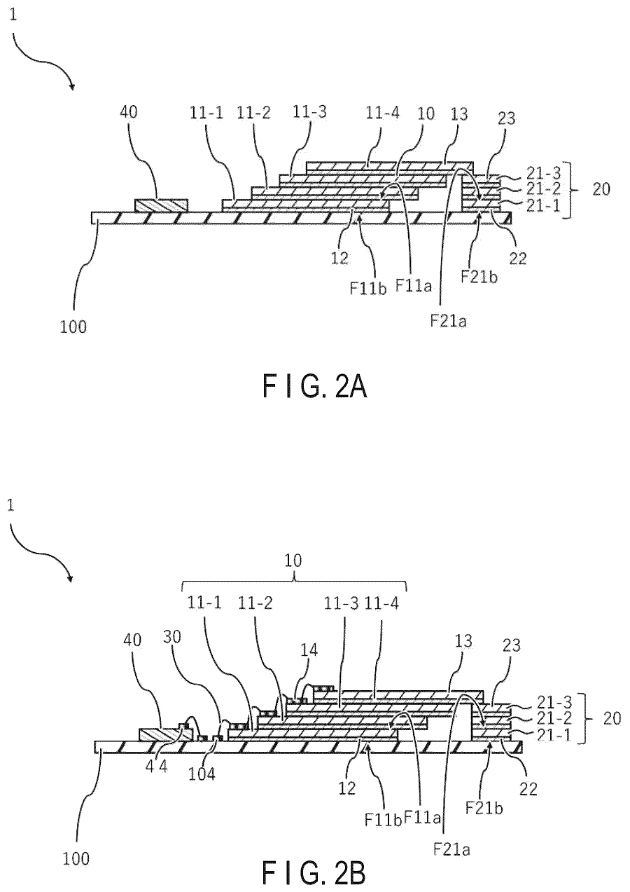

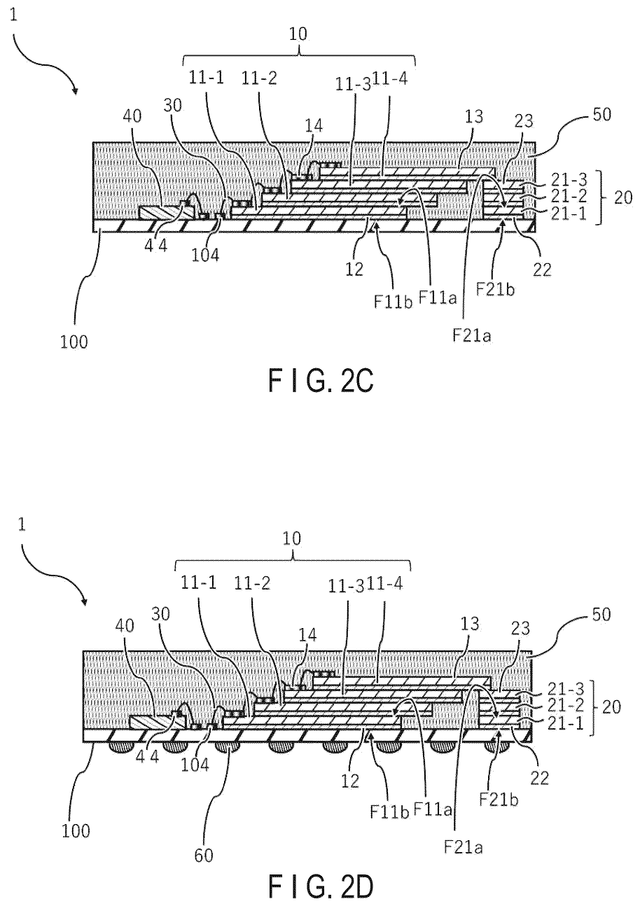

FIG. 2A to FIG. 2D are views illustrating the method of manufacturing the semiconductor device 1 according to the first embodiment.

First, as illustrated in FIG. 2A, the plurality of semiconductor chips 21 are stacked on the substrate 100 to form the stacked body 20. At this time, each of the semiconductor chips 21 is caused to adhere onto another semiconductor chip 21 with the adhesive layer 22.

Next, the plurality of semiconductor chips 11 are stacked on the substrate 100 to form the stacked body 10. At this time, each of the semiconductor chips 11 is caused to adhere onto another semiconductor chip 11 with the adhesive layer 12. At this time, the stacked body 10 is formed such that the second surface F11b of any one of the plurality of semiconductor chips 11 and the first surface F21a of any one of the plurality of semiconductor chips 21 are in contact. For example, as illustrated in FIG. 2A, the stacked body 10 is formed such that the second surface F11b of any one of the plurality of semiconductor chips 11 and the first surface F21a of the semiconductor chip 21 positioned in the uppermost layer of the stacked body 20 (that is, the semiconductor chip 21-3) are in contact. It is to be noted that the stacked body 20 may be formed after a part of the stacked body 10 is formed, or the stacked body 10 may be formed after a part of the stacked body 20 is formed.

It is preferred to stack, as the semiconductor chip 21-1, a semiconductor chip acquired from the same wafer as the semiconductor chip 11-1, stack, as the semiconductor chip 21-2, a semiconductor chip acquired from the same wafer as the semiconductor chip 11-2, and stack, as the semiconductor chip 21-3, a semiconductor chip acquired from the same wafer as the semiconductor chip 11-3.

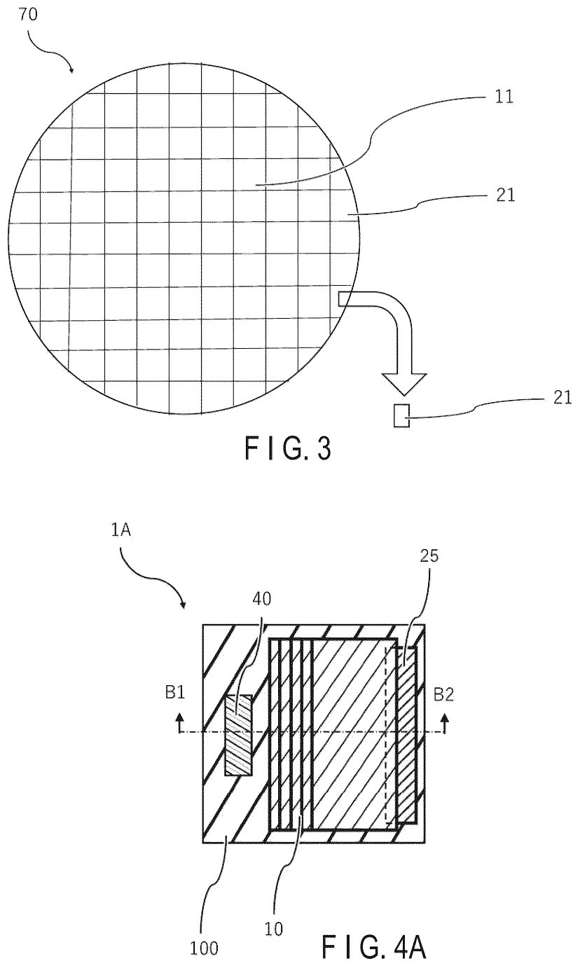

FIG. 3 is a view illustrating a method of acquiring the semiconductor chip 11 and the semiconductor chip 21 according to the first embodiment.

First, a wafer 70 including a silicon substrate having a circuit by a known method is prepared. The circuit includes wiring. The circuit includes, for example, a CMOS circuit or a memory cell array. The wafer 70 may include, for example, an adhesive layer such as a DAF.

The semiconductor chip 11 is diced and acquired from the circular wafer 70 as illustrated in FIG. 3. At this time, a chip that is diced from a region in the vicinity of an end portion of the wafer 70 and does not satisfy the defined size is unsuitable for the semiconductor chip 11. Further, even when a chip satisfies the defined size, a defective chip in which a defect is found in an inspecting step is unsuitable for the semiconductor chip 11. Those unsuitable chips are used as the semiconductor chips 21. Further, the chip diced from the region in the vicinity of the end portion of the wafer 70 has one side with a curved surface, and hence, for example, this chip is processed into a desired shape such as a rectangular shape to be used as the semiconductor chip 21. As described above, the semiconductor chip 11 and the semiconductor chip 21 are acquired, and the stacked body 10 and the stacked body 20 are formed.

Next, the controller chip 40 is formed on the substrate 100. It is to be noted that either the controller chip 40 or the stacked bodies 10 and 20 may be formed first.

Next, as illustrated in FIG. 2B, the bonding wire 30 is formed on each of the semiconductor chips 11 and the controller chip 40. The bonding wire 30 is formed such that the bonding pad 104 of the substrate 100 and each of the bonding pad 14 of the semiconductor chip 11 and the bonding pad 44 of the controller chip 40 are electrically connected.

Next, as illustrated in FIG. 2C, a structure including the stacked body 10, the stacked body 20, the bonding wire 30, and the controller chip 40 is covered with the resin layer 50.

After the resin layer 50 is formed, the resin layer 50 is cured by heating the resin layer 50 with an oven or the like, or by irradiating the resin layer 50 with UV (Ultraviolet) light.

Next, as illustrated in FIG. 2D, the metal terminal 60 is formed on the substrate 100. The metal terminal 60 may be formed by using, for example, ball mounting, a plating method, or a printing method.

As described above, in the semiconductor device 1 of the first embodiment, it is preferred that the semiconductor chip 21-1 be acquired from the same wafer as the semiconductor chip 11-1, the semiconductor chip 21-2 be acquired from the same wafer as the semiconductor chip 11-2, and the semiconductor chip 21-3 be acquired from the same wafer as the semiconductor chip 11-3. Accordingly, the stacked body 10 and the stacked body 20 respectively include semiconductor chips that partially have the same circuit formed thereon, and contain the same material. Further, the thickness of one wafer is uniform, and hence the height obtained by subtracting the height of the semiconductor chip 11-4 out of the semiconductor chips 11 from the height of the stacked body 10 is equivalent to the height of the stacked body 20. At this time, in the stacking direction, the first surface F11a of the semiconductor chip 11-1 is at the same position as the first surface F21a of the semiconductor chip 21-1, the first surface F11a of the semiconductor chip 11-2 is at the same position as the first surface F21a of the semiconductor chip 21-2, and the first surface F11a of the semiconductor chip 11-3 is at the same position as the first surface F21a of the semiconductor chip 21-3.

As described above, according to the first embodiment, the second surface F11b of any one of the plurality of semiconductor chips 11 and the first surface F21a of any one of the plurality of semiconductor chips 21 are in contact. In this manner, the stacked body 20 functions as a spacer that supports the stacked body 10.

### (Comparative Example of First Embodiment)

Hereinafter, a comparative example of the first embodiment is described.

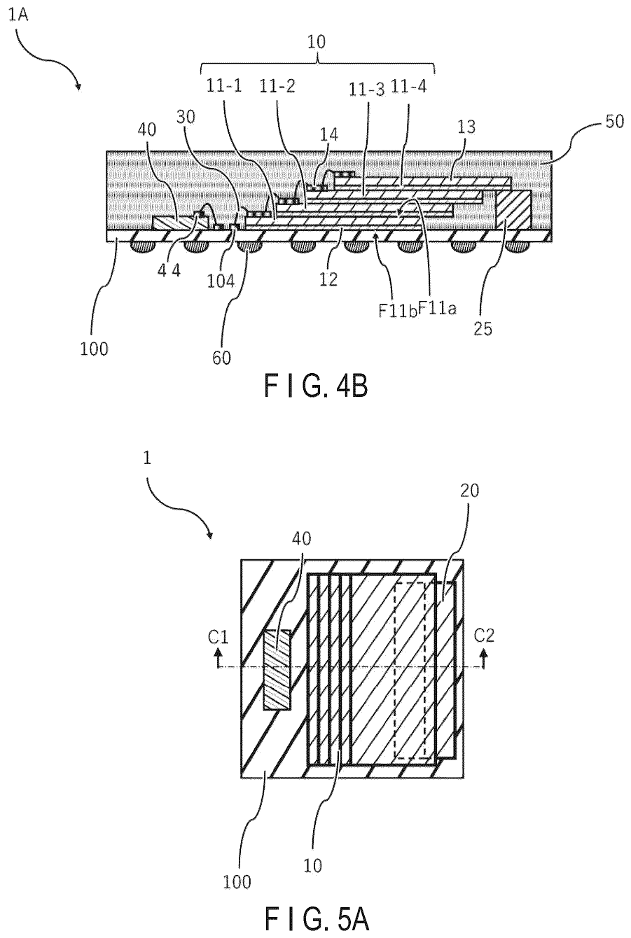

FIG. 4A is a plan view of a semiconductor device 1A according to the comparative example of the first embodiment, and FIG. 4B is a sectional view obtained by taking the semiconductor device 1A of FIG. 4A along a B1-B2 cross section. In FIG. 4A, the bonding wire 30 and the resin layer 50 are omitted.

As illustrated in FIG. 4B, in the semiconductor device 1A of the comparative example, a spacer 25 is mounted as a support for the stacked body 10. The spacer 25 is formed of, for example, a silicon piece.

In the semiconductor device 1A of the comparative example, the spacer 25 is prepared separately from the semiconductor chip 11, and hence it is difficult to align the height of the stacked body 10 and the height of the spacer 25, and there is a possibility of occurrence of non-alignment in height. When the non-alignment in height occurs, a stress load may be generated to the semiconductor chip 11. Further, the stacked body 10 and the spacer 25 include different materials and have different configurations, and hence a difference may be caused in degree of expansion and contraction between the stacked body 10 and the spacer 25 along with temperature change due to the difference in thermal expansion coefficient, resulting in generation of a stress load to the semiconductor chip 11.

In contrast, in the semiconductor device 1 according to the first embodiment, the stacked body 20 supports the stacked body 10 similarly to the spacer 25 in the comparative example. The stacked body 20 includes the semiconductor chip 21 acquired from the same wafer as the semiconductor chip 11 of each stage (that is, at the same position in the stacking direction or at a same distance from the substrate in the stacking direction) of the stacked body 10. Accordingly, the non-alignment in height between the stacked body 10 and the stacked body 20 can be eliminated. Thus, the stress load to the semiconductor chip 11 is balanced.

Further, the thermal expansion coefficients of the semiconductor chip 11 and the semiconductor chip 21 are equivalent, and hence the difference is scarcely caused in the degree of expansion and contraction between the stacked body 10 and the stacked body 20 along with the temperature change. Thus, a local stress load is reduced.

Thus, the semiconductor device 1 according to the first embodiment can be improved in yield at the time of manufacturing the semiconductor device and in reliability of the semiconductor device.

### (Modification Example of First Embodiment)

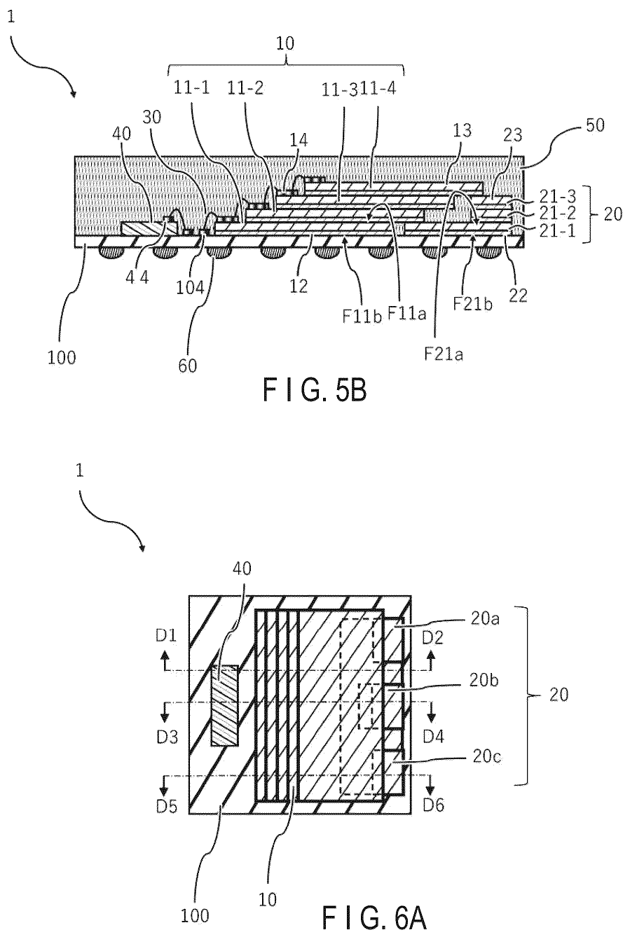

FIG. 5A is a plan view of a semiconductor device 1 according to a modification example of the first embodiment. FIG. 5B is a sectional view obtained by taking the semiconductor device 1 of FIG. 5A along a C1-C2 cross section. In FIG. 5A, the bonding wire 30 and the resin layer 50 are omitted.

As illustrated in FIG. 5B, the first surface F21a of the semiconductor chip 21-1 of the stacked body 20 and the second surface F11b of the semiconductor chip 11-2 of the stacked body 10 may further be in contact.

In the semiconductor device 1 of the modification example, the semiconductor chip 21-1 (e.g., a base semiconductor chip) is larger than other semiconductor chips 21. Here, the base semiconductor chip (larger chip) is not limited to 21-1, but may be 21-2.

As described above in the modification example of the first embodiment, the shapes of the respective semiconductor chips 21 of the stacked body 20 may be different from each other.

### (Second Embodiment)

Hereinafter, a semiconductor device 1 of a second embodiment is described.

The semiconductor device 1 of the second embodiment is different from the first embodiment in that the stacked body 20 is configured of a plurality of blocks of stacked bodies.

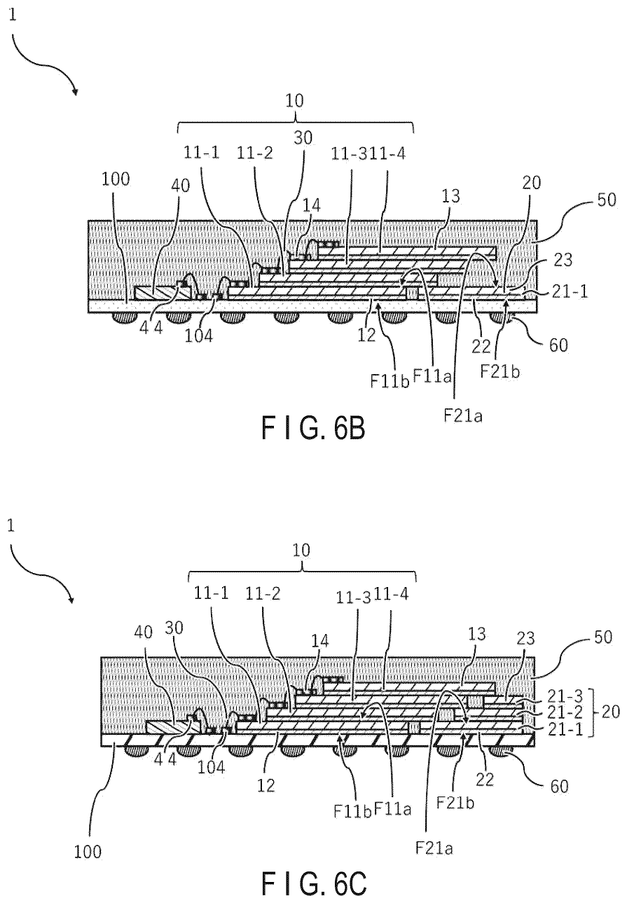

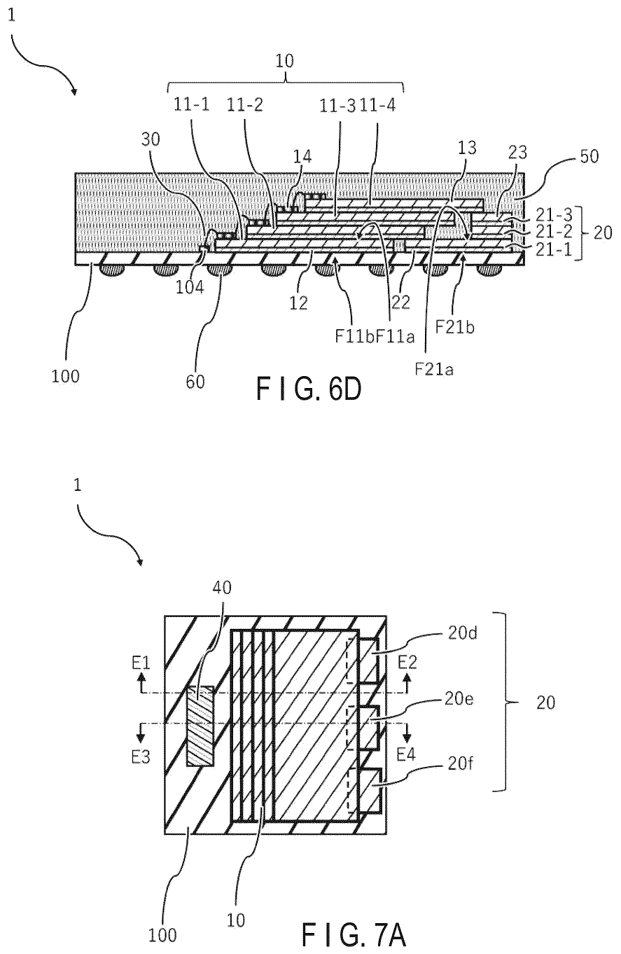

FIG. 6A is a plan view of the semiconductor device 1 according to the second embodiment. FIG. 6B is a sectional view obtained by taking the semiconductor device 1 of FIG. 6A along a D1-D2 cross section. FIG. 6C is a sectional view obtained by taking the semiconductor device 1 of FIG. 6A along a D3-D4 cross section. FIG. 6D is a sectional view obtained by taking the semiconductor device 1 of FIG. 6A along a D5-D6 cross section. In FIG. 6A, the bonding wire 30 and the resin layer 50 are omitted.

With reference to FIG. 6A to FIG. 6D, on the semiconductor chip 21-1 out of the semiconductor chips 21 of the stacked body 20, as a plurality of (e.g., laterally adjacent and spaced apart) blocks (e.g., block of stacked chips), a stacked body 20a, a stacked body 20b, and a stacked body 20c are provided. That is, each of the semiconductor chips 21-2 and 21-3 is divided into a plurality of bodies so that the stacked body 20a, the stacked body 20b, and the stacked body 20c are configured. Further, for example, the semiconductor chip 21-2 of the stacked body 20b is configured to support the semiconductor chip 11-3 of the stacked body 10.

Other configurations and manufacturing method of the semiconductor device 1 according to the second embodiment are similar to the corresponding configurations and manufacturing method of the semiconductor device 1 according to the first embodiment, and hence detailed description thereof is omitted.

As described above with the semiconductor device 1 according to the second embodiment, the stacked body 20 may be configured of a plurality of blocks of stacked bodies.

### (First Modification Example of Second Embodiment)

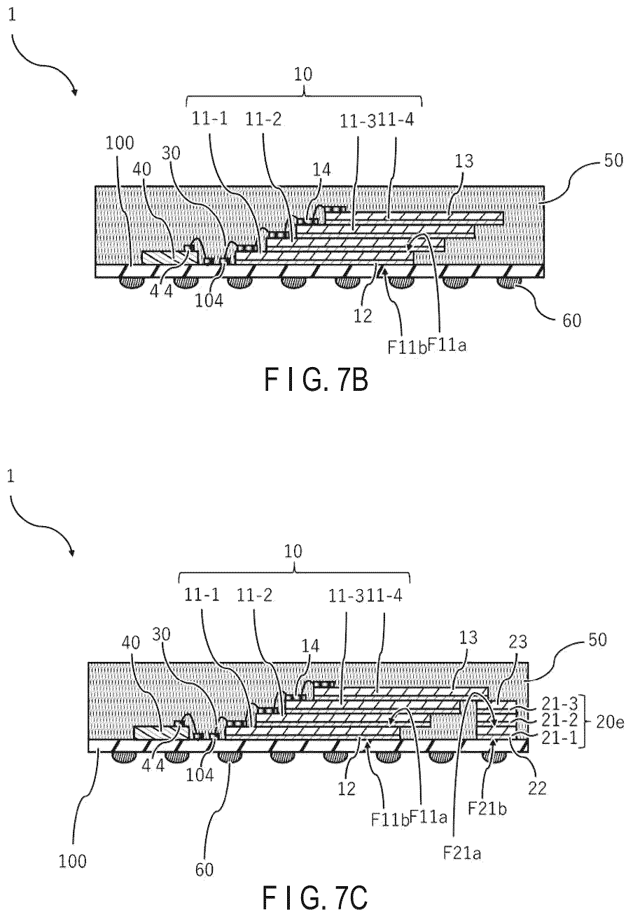

FIG. 7A is a plan view of a semiconductor device 1 according to a first modification example of the second embodiment. FIG. 7B is a sectional view obtained by taking the semiconductor device 1 of FIG. 7A along an E1-E2 cross section. FIG. 7C is a sectional view obtained by taking the semiconductor device 1 of FIG. 7A along an E3-E4 cross section. In FIG. 7A, the bonding wire 30 and the resin layer 50 are omitted.

With reference to FIG. 7A to FIG. 7C, the first modification example is different from the second embodiment in that all of the semiconductor chips 21 constituting the stacked body 20 are divided. At this time, the three divided stacked bodies are referred to as a stacked body 20d, a stacked body 20e, and a stacked body 20f serving as the plurality of blocks.

With reference to FIG. 7A to FIG. 7C, each of the stacked body 20d, the stacked body 20e, and the stacked body 20f supports the stacked body 10. That is, the second surface F11b of the semiconductor chip 11-4 and the first surface F21a of the semiconductor chip 21-3 of each of the stacked body 20d, the stacked body 20e, and the stacked body 20f are in contact. As described above, the stacked body 20 may be configured of a plurality of blocks of stacked bodies.

### (Second Modification Example of Second Embodiment)

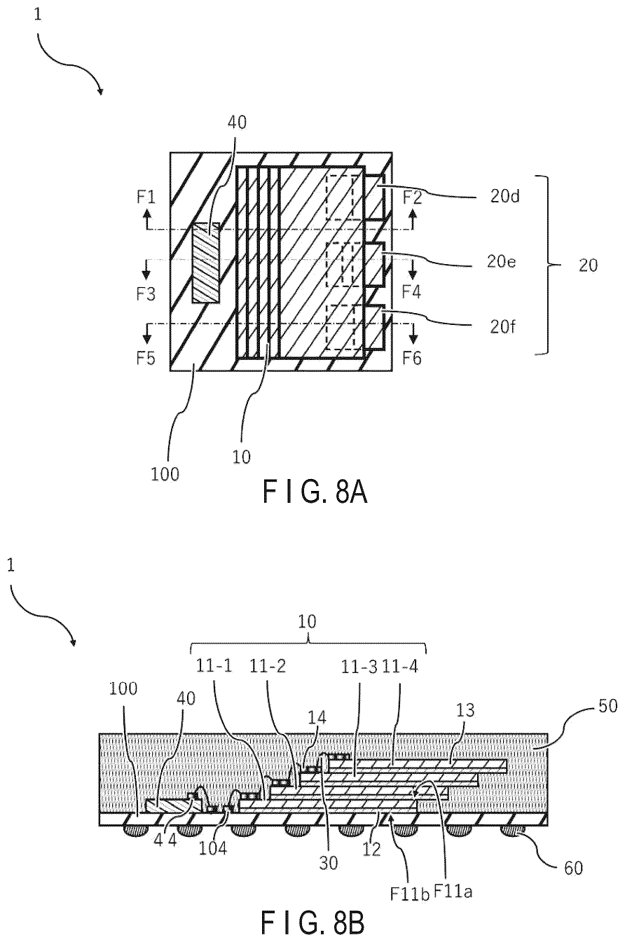

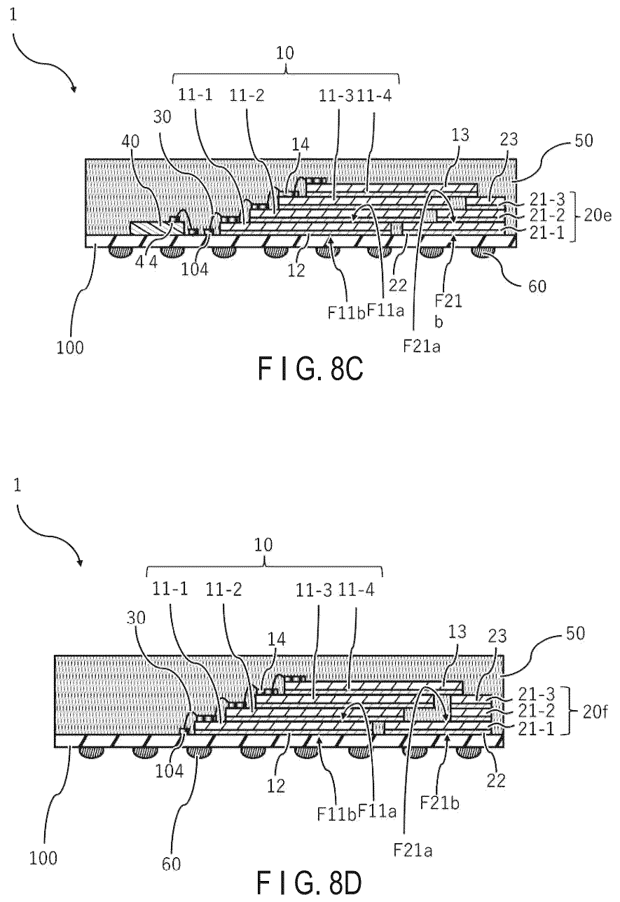

FIG. 8A is a plan view of a semiconductor device 1 according to a second modification example of the second embodiment. FIG. 8B is a sectional view obtained by taking the semiconductor device 1 of FIG. 8A along an F1-F2 cross section. FIG. 8C is a sectional view obtained by taking the semiconductor device 1 of FIG. 8A along an F3-F4 cross section. FIG. 8D is a sectional view obtained by taking the semiconductor device 1 of FIG. 8A along an F5-F6 cross section. In FIG. 8A, the bonding wire 30 and the resin layer 50 are omitted.

With reference to FIG. 8B to FIG. 8D, the semiconductor chips 21 of the stacked body 20d, the stacked body 20e, and the stacked body 20f support the semiconductor chips 11-2, 11-3, and 11-4 of the stacked body 10, and the stacked body 20d and the stacked body 20f support the semiconductor chips 11-2 and 11-4 of the stacked body 10. As described above, the shapes of the semiconductor chips 21 constituting the plurality of stacked bodies may be different from each other.

The semiconductor devices 1 according to the second embodiment and the first and second modification examples thereof can obtain effects similar to those of the first embodiment. Further, in the semiconductor device 1 according to the second embodiment, a part or the whole of the stacked body 20 is divided and is configured of a plurality of blocks of stacked bodies, and hence a space to which a resin flows becomes large. Accordingly, the formation of the resin layer 50 is easier as compared with the first embodiment. Further, the modification example of the first embodiment may be combined with the semiconductor device 1 according to the second embodiment.

### (Third Embodiment)

In the first and second embodiments, description has been given of a case in which the semiconductor chips 11 and 21 require the adhesive layers 12 and 22, but it is also possible to directly stack the chips 13 and 23 without providing the adhesive layers 12 and 22.

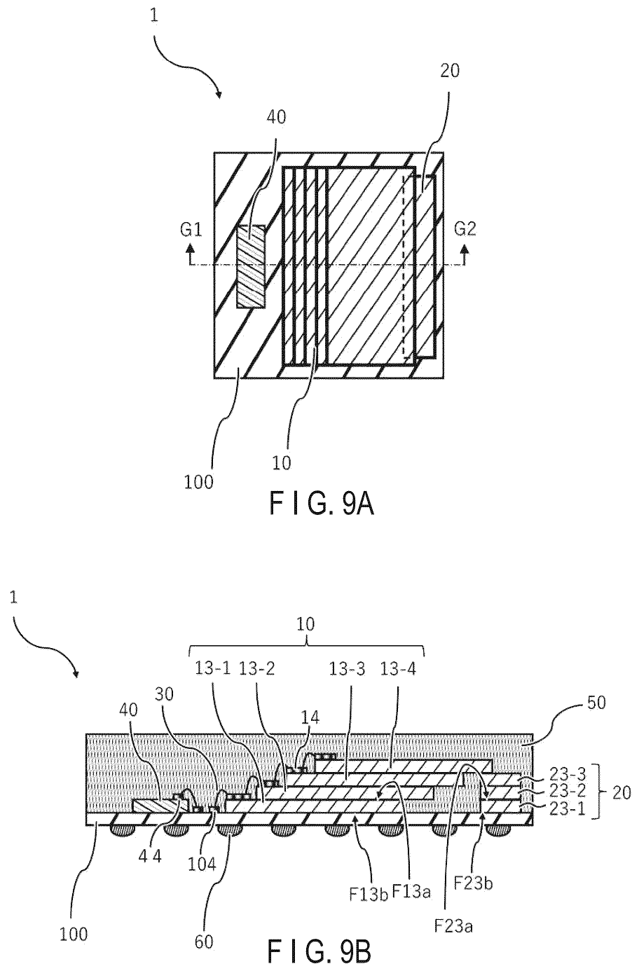

FIG. 9A is a plan view of a semiconductor device 1 according to a third embodiment. FIG. 9B is a sectional view obtained by taking the semiconductor device 1 of FIG. 9A along a G1-G2 cross section. In FIG. 9A, the bonding wire 30 and the resin layer 50 are omitted.

In the first and second embodiments, description has been given of the semiconductor chip 11 including the chip 13 and the adhesive layer 12, and the semiconductor chip 21 including the chip 23 and the adhesive layer 22, but each of the adhesive layers 12 and 22 is not required to be provided.

With reference to FIG. 9B, the stacked body 10 of the semiconductor device 1 of the third embodiment is configured of chips 13-1, 13-2, 13-3, and 13-4, and does not include the adhesive layer 12. The chips 13-1, 13-2, 13-3, and 13-4 are each, for example, a memory chip such as a NAND flash memory or a DRAM, and include a memory cell array or a CMOS circuit.

The chip 13-1, the chip 13-2, the chip 13-3, and the chip 13-4 each have a first surface F13a and a second surface F13b on a side opposite to the first surface. The first surface F13a of each of the chips 13 includes the bonding pad 14.

Further, the stacked body 20 of the semiconductor device 1 is configured of chips 23-1, 23-2, and 23-3, and does not include the adhesive layer 22. The chips 23-1, 23-2, and 23-3 are each, for example, a memory chip such as a NAND flash memory or a DRAM, and include a memory cell array or a CMOS circuit.

The chip 23-1, the chip 23-2, and the chip 23-3 each have a first surface F23a and a second surface F23b on a side opposite to the first surface. The chips 23-1, 23-2, and 23-3 are electrically isolated from each other.

Other configurations of the semiconductor device 1 according to the third embodiment are similar to the corresponding configurations of the semiconductor device 1 according to the first embodiment, and hence detailed description thereof is omitted.

The chips 13-1 and 13-2, the chips 13-2 and 13-3, and the chips 13-3 and 13-4 are caused to adhere to each other by, for example, plasma processing of the chip surface.

It is to be noted that the third embodiment is not limited to the structure of the semiconductor device 1 of FIG. 9B, and also includes configurations in which the adhesive layers 12 and 22 are not provided in all configurations described in the first and second embodiments and the modification examples thereof.

While certain embodiments have been described, these embodiments have been presented by way of example only, and are not intended to limit the scope of the application. Indeed, the novel devices and methods described herein may be embodied in a variety of other forms; furthermore, various omissions, substitutions and changes in the form of the embodiments described herein may be made without departing from the spirit of the embodiments. The accompanying claims and their equivalents are intended to cover such forms or modification as would fall within the scope and spirit of the embodiments.

What is claimed is

1. A semiconductor device comprising:
a substrate;
a first stacked body on the substrate, the first stacked body including a plurality of first semiconductor chips that are stacked while being shifted in a direction perpendicular to a stacking direction; and
a second stacked body on the substrate, the second stacked body including a plurality of second semiconductor chips that are stacked in the stacking direction, wherein
an upper surface of at least one of the plurality of second semiconductor chips and a lower surface of at least one of the plurality of first semiconductor chips are in contact.

2. The semiconductor device of claim 1, wherein:
the substrate includes an electrode thereon, and
each of the plurality of first semiconductor chips is electrically connected to the electrode on the substrate.

3. The semiconductor device of claim 1, wherein each of the plurality of first semiconductor chips are configured of a memory chip and a Die Attach Film.

4. The semiconductor device of claim 1, wherein:
each of the plurality of first semiconductor chips includes a memory chip, and
the upper surface of the at least one of the plurality of second semiconductor chips and the lower surface of the at least one of the plurality of first semiconductor chips are in direct contact.

5. The semiconductor device of claim 1, wherein one of the plurality of first semiconductor chips and a corresponding one of the plurality of second semiconductor chips at a same position in the stacking direction have a same thickness.

6. The semiconductor device of claim 1, wherein shapes of at least two of the second semiconductor chips constituting the second stacked body are different from each other.

7. The semiconductor device of claim 1, wherein the second stacked body includes:
a first block in which the plurality of second semiconductor chips are stacked, and
a second block in which the plurality of second semiconductor chips are stacked.

8. The semiconductor device of claim 7, wherein the second stacked body further includes a base second semiconductor chip that is between the substrate and the first block and is larger than the plurality of second semiconductor chips included in the first block.

9. The semiconductor device of claim 1, wherein the plurality of second semiconductor chips are electrically isolated from each other.

10. A semiconductor device comprising:
a substrate;
a first stacked body on the substrate, the first stacked body including a plurality of first semiconductor chips that are stacked while being shifted in a direction perpendicular to a stacking direction; and
a second stacked body on the substrate, the second stacked body including a plurality of second semiconductor chips that are stacked in the stacking direction, the second stacked body supporting the first stacked body, wherein
the second semiconductor chips each have a circuit thereon.

11. The semiconductor device of claim 10, wherein:
the substrate includes an electrode thereon, and
each of the plurality of first semiconductor chips is electrically connected to the electrode on the substrate.

12. The semiconductor device of claim 10, wherein each of the plurality of first semiconductor chips are configured of a memory chip and a Die Attach Film.

13. The semiconductor device of claim 10, wherein:
each of the plurality of first semiconductor chips includes a memory chip, and
an upper surface of the at least one of the plurality of second semiconductor chips and a lower surface of the at least one of the plurality of first semiconductor chips are in direct contact.

14. The semiconductor device of claim 10, wherein one of the plurality of first semiconductor chips and a corresponding one of the plurality of second semiconductor chips at a same position in the stacking direction have a same thickness.

15. The semiconductor device of claim 10, wherein shapes of at least two of the second semiconductor chips constituting the second stacked body are different from each other.

16. The semiconductor device of claim 10, wherein the second stacked body includes:
a first block in which the plurality of second semiconductor chips are stacked, and
a second block in which the plurality of second semiconductor chips are stacked.

17. The semiconductor device of claim 16, wherein the second stacked body further includes a base second semiconductor chip that is between the substrate and the first block and is larger than the plurality of second semiconductor chips included in the first block.

18. The semiconductor device of claim 10, wherein the plurality of second semiconductor chips are electrically isolated from each other.

19. A method of manufacturing a semiconductor device, the method comprising:
forming, on a substrate, a first stacked body including a plurality of first semiconductor chips that are stacked while being shifted in a direction perpendicular to a stacking direction; and
forming, on the substrate, a second stacked body including a plurality of second semiconductor chips that are stacked in the stacking direction, wherein
forming the first stacked body and forming the second stacked body are carried out so that an upper surface of at least one of the plurality of second semiconductor chips and a lower surface of at least one of the plurality of first semiconductor chips are in contact.

20. The method of manufacturing a semiconductor device of claim 19, wherein the forming plurality of the second stacked body is carried out by using the second semiconductor chips each having have a circuit formed thereon.
